(19) United States
(12) Patent Application Publication
(10) Pub. No.: US 2024/0030279 A1
(43) Pub. Date: Jan. 25, 2024

(54) Semiconductor Structure and Method for Forming the Same

(71) Applicants: HUA HONG SEMICONDUCTOR (WUXI) LIMITED, Wuxi (CN); SHANGHAI HUAHONG GRACE SEMICONDUCTOR MANUFACTURING CORPORATION, Shanghai (CN)

(72) Inventors: Zhengrong CHEN, Wuxi (CN); Wensheng Qian, Shanghai (CN); Sitong Chen, Wuxi (CN); Zhaozhao Xu, Wuxi (CN); Wan Song, Wuxi (CN); Donghua Liu, Shnaghai (CN); Leping Wei, Wuxi (CN)

(21) Appl. No.: 18/138,380

(22) Filed: Apr. 24, 2023

(30) Foreign Application Priority Data
Jul. 21, 2022 (CN) 202210872861.3

(51) Int. Cl. H01L 29/06; H01L 21/265

(52) U.S. Cl. CPC H01L 29/0623; H01L 21/26513

(57) ABSTRACT

The present disclosure provides a semiconductor structure and a method for forming the semiconductor structure. The method includes: providing a substrate including a device region and a guard ring region surrounding the device region; and forming a power device in the device region and forming a guard ring in the guard ring region, wherein the guard ring is doped with a first dopant ion that is formed by a partial doping process used in a formation of the power device, and a conductivity type of the first dopant ion in the guard ring is different from a device type of the power device. Since the guard ring is formed by the necessary doping process used in forming the power device, additional photomask process and doping process for forming the guard ring is omitted, effectively reducing process steps and process costs.

### CROSS-REFERENCE TO RELATED APPLICATIONS

This application claims the benefit of priority to Chinese patent application No. 202210872861.3, filed on Jul. 21, 2022, the entire disclosures of which are incorporated herein by reference.

### TECHNICAL FIELD

The present disclosure relates to the technical field of semiconductors, and more particularly to a semiconductor structure and a method for forming the semiconductor structure.

### BACKGROUND OF THE INVENTION

Power devices are almost used in all electronic manufacturing industries, including laptops, PCs, servers, displays, and various peripherals in computer field, mobile phones, telephones, and other various terminals and office equipments in network communication field, traditional black and white household appliances and various digital products in consumer electronic field, industrial PCs, various instruments and meters, and various control equipments in industrial control category.

In the power devices, in order to reduce the problem of breakdown voltage decrease which is mainly caused by an electric field intensity in an edge cylindrical region or a corner spherical region of a main junction being greater than that of a planar junction, a guard ring is usually disposed in an outer ring of a device region of the device.

However, there are still many problems in the process for forming the power devices.

### SUMMARY OF THE INVENTION

The present disclosure aims to provide a semiconductor structure and a method for forming the semiconductor structure, in order to reduce process steps and process costs.

According to an aspect of the present disclosure, a method for forming a semiconductor structure includes: providing a substrate including a device region and a guard ring region surrounding the device region; and forming a power device in the device region and forming a guard ring in the guard ring region, wherein the guard ring is doped with a first dopant ion that is formed by a partial doping process used in forming the power device, and a conductivity type of the first dopant ion in the guard ring is different from a device type of the power device.

In some embodiments, the doping process includes an ion implantation doping process or an epitaxial growth doping process.

In some embodiments, the guard ring is doped with a second dopant ion having a conductivity type different from the conductivity type of the first dopant ion, and a top surface of the guard ring is lower than a top surface of the substrate.

In some embodiments, the top surface of the guard ring is flush with the top surface of the substrate.

In some embodiments, when the power device is a P-type power device, the first dopant ion in the guard ring is N-type ion.

In some embodiments, when the power device is an N-type power device, the first dopant ion in the guard ring is P-type ion.

According to another aspect of the present disclosure, a semiconductor structure includes: a substrate including a device region and a guard ring region surrounding the device region; a power device disposed in the device region; and a guard ring disposed in the guard ring region, wherein the guard ring is doped with a first dopant ion, and a conductivity type of the first dopant ion in the guard ring is different from a device type of the power device.

In some embodiments, the guard ring is doped with a second dopant ion having a conductivity type different from the conductivity type of the first dopant ion, and a top surface of the guard ring is lower than a top surface of the substrate.

In some embodiments, wherein the top surface of the guard ring is flush with the top surface of the substrate.

In some embodiments, when the power device is a P-type power device, the first dopant ion in the guard ring is N-type ion.

In some embodiments, when the power device is an N-type power device, the first dopant ion in the guard ring is P-type ion.

In the method for forming the semiconductor structure according to the embodiments of the present disclosure, the power device is formed in the device region, and the guard ring is formed in the guard ring region. The guard ring is doped with a first dopant ion that is formed by a partial doping process used in forming the power device, and a conductivity type of the first dopant ion in the guard ring is different from a device type of the power device. Since the guard ring is formed in the necessary doping process used in forming the power device, additional photomask process and doping process for forming the guard ring is not needed, which can effectively reduce process steps and process costs.

Further, the guard ring is doped with a second dopant ion having a conductivity type different from the conductivity type of the first dopant ion, and a top surface of the guard ring is lower than a top surface of the substrate. Since an ion implantation doping process is sometimes used in the partial doping process used in forming the power device, and the ion implantation doping process often has large injection energy, the top surface of the formed guard ring may be lower than the top surface of the substrate. Since the first dopant ion in the guard ring and the second dopant ion in the guard ring have different conductivity types, the substrate disposed on the guard ring forms a completely depleted layer with the guard ring, which can reduce the problem that an electric field intensity in an edge cylindrical region or a corner spherical region of a main junction is greater than that of a planar junction, thereby achieving an effect of improving the breakdown voltage.

In the semiconductor structure according to the embodiments of the present disclosure, the guard ring is disposed in the guard ring region, the guard ring is doped with a first dopant ion, and a conductivity type of the first dopant ion in the guard ring is different from a device type of the power device. Since the guard ring is formed in the necessary doping process used in forming the power device, additional photomask process and doping process for forming the guard ring is not needed, which can effectively reduce process steps and process costs.

Further, the guard ring is doped with a second dopant ion having a conductivity type different from the conductivity type of the first dopant ion, and a top surface of the guard ring is lower than a top surface of the substrate. Since an ion implantation doping process is sometimes used in the partial doping process used in forming the power device, and the ion implantation doping process often has large injection energy, the top surface of the formed guard ring may be lower than the top surface of the substrate. Since the first dopant ion in the guard ring and the second dopant ion in the guard ring have different conductivity types, the substrate disposed on the guard ring forms a completely depleted layer with the guard ring, which can reduce the problem that an electric field intensity in an edge cylindrical region or a corner spherical region of a main junction is greater than that of a planar junction, thereby achieving an effect of improving the breakdown voltage.

### BRIEF DESCRIPTION OF THE DRAWINGS

FIGS. 1 to 4 are schematic structural views illustrating steps of a method for forming a semiconductor structure according to an embodiment of the present disclosure.

### DETAILED DESCRIPTION OF THE EMBODIMENTS

As described in the background, there are still many problems in the process for forming the power devices, which will be described in detail below.

The manufacturing processes of the existing power devices and the guard ring are independent of each other, so it is necessary to add an additional photomask process and a doping process to form the guard ring, thereby increasing manufacturing steps and process costs.

On this basis, the present disclosure provides a semiconductor structure and a method for forming the semiconductor structure, wherein the power device is formed in the device region, and the guard ring is formed in the guard ring region, wherein the guard ring is doped with a first dopant ion that is formed by a partial doping process used in forming the power device, and a conductivity type of the first dopant ion in the guard ring is different from a device type of the power device. Since the guard ring is formed in the necessary doping process used in forming the power device, additional photomask process and doping process for forming the guard ring is not needed, effectively reducing process steps and process costs.

In order to make above objectives, features, and advantages of the present disclosure more apparent and understandable, specific embodiments of the present disclosure will be described in detail below in conjunction with the accompanying drawings.

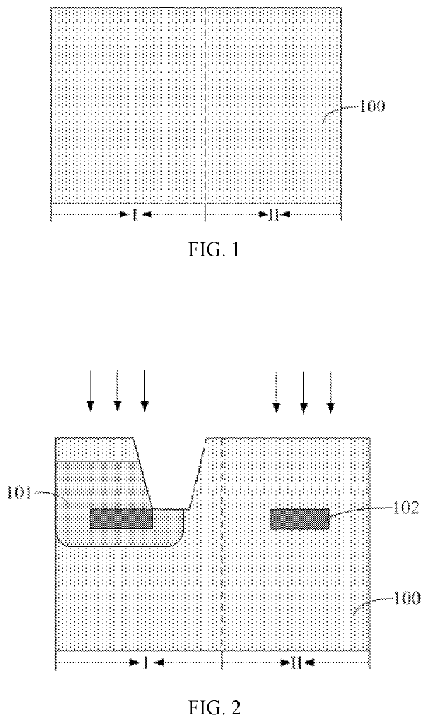

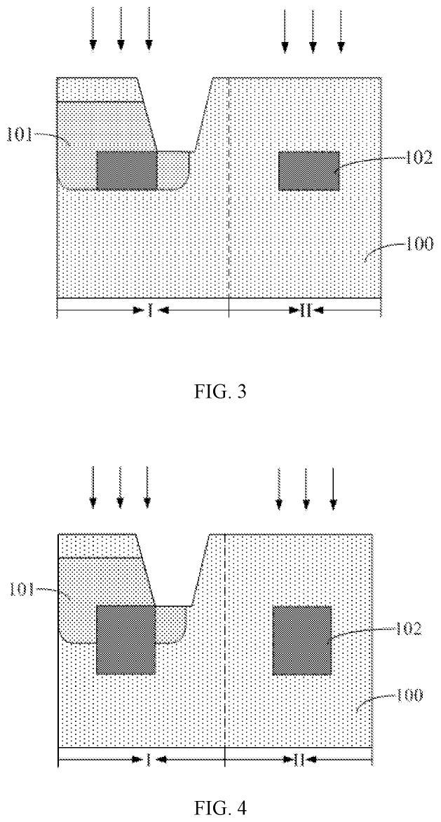

FIGS. 1 to 4 are schematic structural views illustrating steps of a method for forming a semiconductor structure according to an embodiment of the present disclosure.

Referring to FIG. 1, a substrate 100 is provided. The substrate 100 includes a device region I and a guard ring region II surrounding the device region I.

In some embodiments, the material of the substrate 100 is silicon. In other embodiments, the material of the substrate may also be germanium, silicon germanium, silicon carbide, gallium arsenide, or indium gallium.

In some embodiments, the device region I is used to subsequently form a power device therein, and the guard ring region II is used to subsequently form a guard ring therein. In the power device, an electric field intensity in an edge cylindrical region or a corner spherical region of a main junction is greater than that of a planar junction, which can easily lead to a reduce of a breakdown voltage. Therefore, it is necessary to add the guard ring to increase the breakdown voltage.

Referring to FIGS. 2 to 4, a power device 101 is formed in the device region I, and a guard ring 102 is formed in the guard ring region II. The guard ring 102 is doped with a first dopant ion. The first dopant ion in the guard ring 102 is formed by a partial doping process used in forming the power device 101, and a conductivity type of the first dopant ion in the guard ring 102 is different from a device type of the power device 101.

Since the power device 101 is composed of multiple transistor structures in parallel, a doping process is required in the process for forming a main body, Pwel and Nplus of the transistor structures and a high concentration doping region at a bottom of a conductive plug for reducing contact resistance.

In some embodiments, since the guard ring 102 is formed in the necessary doping process used in forming the power device 101, the additional use of a photomask process and a doping process to form the guard ring 102 is not needed, which can effectively reduce process steps and process costs.

In some embodiments, the doping process adopts an ion implantation doping process. It should be noted that before the synchronous ion implantation doping process in the guard ring region II, it is also necessary to define an ion implantation position in the guard ring region II by relying on a mask used to form the power device 101.

Still referring to FIGS. 2 to 4, in some embodiments, the guard ring 102 is formed by three ion implantation doping processes.

In other embodiments, the doping process may also adopt an epitaxial growth doping process. It should be noted that before the synchronous epitaxial growth doping process in the guard ring region, it is also necessary to define an epitaxial growth position in the guard ring region by relying on a mask used to form the power device. After defining the epitaxial growth position in the guard ring region, it is also necessary to etch an initial groove in the guard ring region.

In some embodiments, the guard ring region II is doped with a second dopant ion, and a conductivity type of the second dopant ion is different from that of the first dopant ion. A top surface of the guard ring 102 is lower than a top surface of the substrate 100.

In some embodiments, since an ion implantation doping process is used in the partial doping process used in forming the power device 101, and the ion implantation doping process often has large injection energy, the top surface of the formed guard ring 102 may be lower than the top surface of the substrate. Since the first dopant ion in the guard ring 102 and the second dopant ion in the guard ring region II have different conductivity types, the substrate 100 disposed on the guard ring 102 forms a completely depleted layer with the guard ring 102, which can reduce the problem that the electric field intensity in the edge cylindrical region or the corner spherical region of the main junction is greater than that of the planar junction, thereby achieving an effect of improving the breakdown voltage.

In other embodiments, the top surface of the guard ring is flush with the top surface of the substrate.

In some embodiments, when the power device 101 is an N-type power device, the first dopant ion in the guard ring is P-type ion.

In some embodiments, when the power device 101 is a P-type power device, the first dopant ion in the guard ring is N-type ion.

Accordingly, another embodiment of the present disclosure further provides a semiconductor structure formed by the method according to above embodiments of the present disclosure. Referring to FIG. 4, the semiconductor structure includes a substrate 100, a power device 101 and a guard ring 102. The substrate 100 includes a device region I and a guard ring region II surrounding the device region I. The power device 101 is disposed in the device region I, and the guard ring 102 is disposed in the guard ring region II. The guard ring 102 is doped with a first dopant ion, and a conductivity type of the first dopant ion in the guard ring 102 is different from a device type of the power device 101.

In some embodiments, since the guard ring 102 is formed using the necessary doping process used in forming the power device 101, the additional photomask process and doping process to form the guard ring 102 is not needed, which can effectively reduce process steps and process costs.

In some embodiments, the guard ring 102 is doped with a second dopant ion having a conductivity type different from the conductivity type of the first dopant ion, and a top surface of the guard ring 102 is lower than a top surface of the substrate 100. Since an ion implantation doping process is sometimes used in the partial doping process used in forming the power device 101, and the ion implantation doping process often has large injection energy, the top surface of the formed guard ring 102 may be lower than the top surface of the substrate 100. Since the first dopant ion in the guard ring 102 and the second dopant ion in the guard ring have different conductivity types, the substrate disposed on the guard ring forms a completely depleted layer with the guard ring 102, which can reduce the problem that the electric field intensity in an edge cylindrical region or a corner spherical region of a main junction is greater than that of a planar junction, thereby achieving an effect of improving a breakdown voltage.

In other embodiments, the top surface of the guard ring is flush with the top surface of the substrate.

In some embodiments, when the power device 101 is an N-type power device, the first dopant ion in the guard ring is P-type ion.

In some embodiments, when the power device 101 is a P-type power device, the first dopant ion in the guard ring is N-type ion.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. A method for forming a semiconductor structure, comprising:
providing a substrate comprising a device region and a guard ring region surrounding the device region; and
forming a power device in the device region and forming a guard ring in the guard ring region, wherein the guard ring is doped with a first dopant ion that is formed by a partial doping process used in forming the power device, and a conductivity type of the first dopant ion in the guard ring is different from a device type of the power device.

2. The method according to claim 1, wherein the doping process comprises an ion implantation doping process or an epitaxial growth doping process.

3. The method according to claim 1, wherein the guard ring is doped with a second dopant ion having a conductivity type different from the conductivity type of the first dopant ion, and a top surface of the guard ring is lower than a top surface of the substrate.

4. The method according to claim 1, wherein a top surface of the guard ring is flush with a top surface of the substrate.

5. The method according to claim 1, wherein when the power device is a P-type power device, the first dopant ion in the guard ring is N-type ion.

6. The method according to claim 1, wherein when the power device is an N-type power device, the first dopant ion in the guard ring is P-type ion.

7. A semiconductor structure formed by the method according to claim 1, comprising:
the substrate comprising the device region and the guard ring region surrounding the device region;
the power device disposed in the device region; and
the guard ring disposed in the guard ring region, wherein the guard ring is doped with the first dopant ion, and the conductivity type of the first dopant ion in the guard ring is different from the device type of the power device.

8. The semiconductor structure according to claim 7, wherein the guard ring is doped with a second dopant ion having a conductivity type different from the conductivity type of the first dopant ion, and a top surface of the guard ring is lower than a top surface of the substrate.

9. The semiconductor structure according to claim 7, wherein a top surface of the guard ring is flush with a top surface of the substrate.

10. The semiconductor structure according to claim 7, wherein when the power device is a P-type power device, the first dopant ion in the guard ring is N-type ion.

11. The semiconductor structure according to claim 7, wherein when the power device is an N-type power device, the first dopant ion in the guard ring is P-type ion.
